(19) United States
(12) Patent Application Publication
(10) Pub. No.: US 2023/0421132 A1
(43) Pub. Date: Dec. 28, 2023

(54) RESONATOR DEVICE

(71) Applicant: SEIKO EPSON CORPORATION, Tokyo (JP)

(72) Inventor: Yoko Kanemoto, Fujimi-machi (JP)

(21) Appl. No.: 18/339,550

(22) Filed: Jun. 22, 2023

(30) Foreign Application Priority Data
Jun. 24, 2022 (JP) 2022-101662

(51) Int. Cl. H03H 9/19; H03H 9/05; H03H 3/02

(52) U.S. Cl. CPC H03H 9/19; H03H 3/02; H03H 9/0595

(57) ABSTRACT

A resonator device includes a quartz crystal vibrating plate having a vibrating part and a frame part configured to surround the vibrating part in a plan view, a first sealing member bonded to one surface side of the quartz crystal vibrating plate, a second sealing member bonded to another surface side of the quartz crystal vibrating plate, and a bonding layer, wherein at least one of the first sealing member and the second sealing member is a film, and the film is bonded to the frame part via the bonding layer, and has an area where the bonding layer does not exist on a surface at the vibrating part side.

The present application is based on, and claims priority from JP Application Serial Number 2022-101662, filed Jun. 24, 2022, the disclosure of which is hereby incorporated by reference herein in its entirety.

### BACKGROUND

### 1. Technical Field

The present disclosure relates to a resonator device.

### 2. Related Art

In JP-A-2020-141264 (Document 1), there is disclosed a piezoelectric resonator device provided with a quartz crystal vibrating plate having an outer frame, a first resin film coupled to the outer frame at one principal surface side of the quartz crystal vibrating plate, and a second resin film coupled to the outer frame at the other principal surface side of the quartz crystal vibrating plate.

According to Document 1, the first resin film and the second resin film are thermocompression-bonded to the outer frame using hot press via a bonding layer formed in the entire areas of both of obverse and reverse surfaces. When mounting the quartz crystal vibrating plate on an external substrate, there is used a solder-reflow process or the like higher in temperature than the hot press.

However, in the technology described in Document 1, since the bonding layer is formed on the entire surface of the resin film, there is a problem that when using the solder-reflow process, a solvent and so on evaporate from the bonding layer to cause outgassing, and there is a possibility that a harmful influence is exerted on the frequency fluctuation of the quarts crystal vibrating plate and so on.

### SUMMARY

A resonator device includes a vibrating plate having a vibrating part and a frame part configured to surround the vibrating part in a plan view, a first sealing member bonded to one surface side of the vibrating plate, a second sealing member bonded to another surface side of the vibrating plate, and a bonding layer, wherein at least one of the first sealing member and the second sealing member is a resin film, and the resin film is bonded to the frame part via the bonding layer, and has an area where the bonding layer does not exist on a surface at the vibrating part side.

### BRIEF DESCRIPTION OF THE DRAWINGS

FIG. 1 is a perspective view showing a configuration of a resonator device according to a first embodiment.

FIG. 2 is a plan view showing a configuration of the resonator device.

FIG. 3 is a cross-sectional view of the resonator device along a line A-A shown in FIG. 2.

FIG. 4 is a plan view showing a configuration of the resonator device.

FIG. 5A is a cross-sectional view showing a method of manufacturing the resonator device.

FIG. 5B is a cross-sectional view showing the method of manufacturing the resonator device.

FIG. 5C is a cross-sectional view showing the method of manufacturing the resonator device.

FIG. 5D is a cross-sectional view showing the method of manufacturing the resonator device.

FIG. 5E is a cross-sectional view showing the method of manufacturing the resonator device.

FIG. 6 is a plan view showing a configuration of a sealing member.

FIG. 7 is a cross-sectional view of the sealing member along a line B-B shown in FIG. 6.

FIG. 8A is a plan view showing a method of manufacturing the sealing member.

FIG. 8B is a plan view showing the method of manufacturing the sealing member.

FIG. 8C is a plan view showing the method of manufacturing the sealing member.

FIG. 9A is a cross-sectional view showing the method of manufacturing the sealing member.

FIG. 9B is a cross-sectional view showing the method of manufacturing the sealing member.

FIG. 9C is a cross-sectional view showing the method of manufacturing the sealing member.

FIG. 10A is a plan view showing a method of manufacturing the sealing member.

FIG. 10B is a plan view showing the method of manufacturing the sealing member.

FIG. 10C is a plan view showing the method of manufacturing the sealing member.

FIG. 11A is a cross-sectional view showing the method of manufacturing the sealing member.

FIG. 11B is a cross-sectional view showing the method of manufacturing the sealing member.

FIG. 11C is a cross-sectional view showing the method of manufacturing the sealing member.

FIG. 12 is a cross-sectional view showing a configuration of a resonator device according to a second embodiment.

FIG. 13A is a cross-sectional view showing a method of manufacturing the resonator device.

FIG. 13B is a cross-sectional view showing the method of manufacturing the resonator device.

FIG. 13C is a cross-sectional view showing the method of manufacturing the resonator device.

FIG. 13D is a cross-sectional view showing the method of manufacturing the resonator device.

FIG. 14 is a cross-sectional view showing a configuration of a resonator device according to a modified example.

FIG. 15 is a plan view showing the configuration of the resonator device according to the modified example.

FIG. 16 is the cross-sectional view showing the configuration of the resonator device according to a modified example.

FIG. 17 is a plan view showing the configuration of the resonator device according to the modified example.

FIG. 18 is a cross-sectional view showing the configuration of the resonator device according to a modified example.

FIG. 19 is a cross-sectional view showing the configuration of the resonator device according to a modified example.

### DESCRIPTION OF EXEMPLARY EMBODIMENTS

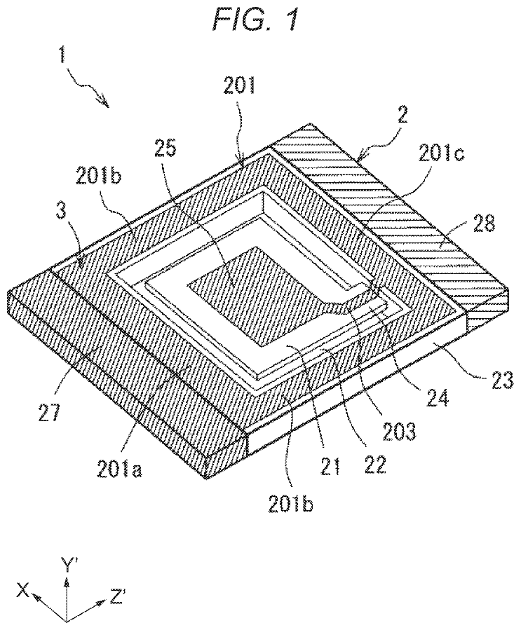

First, a configuration of a resonator device 1 will be described with reference to FIG. 1 through FIG. 4.

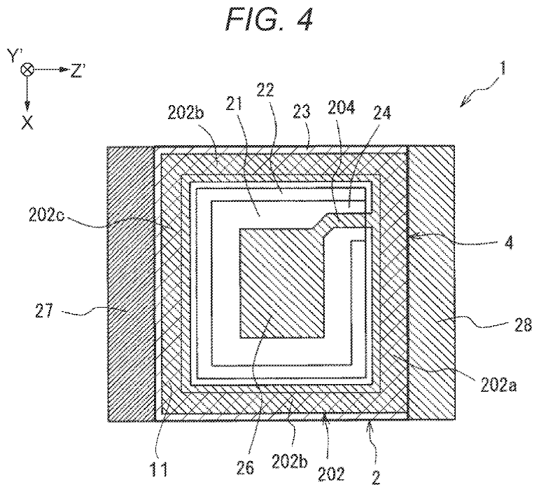

As shown in FIG. 1, the resonator device 1 is provided with a quartz crystal vibrating plate 2 as a vibrating plate, a first sealing member 3 which covers one principal surface side out of both of obverse and reverse principal surfaces of the quartz crystal vibrating plate 2 to seal the one principal surface side, and a second sealing member 4 (see FIG. 4) which covers the other principal surface side to seal the other principal surface side.

The first sealing member 3 and the second sealing member 4 are each, for example, a resin film. The resonator device 1 is a rectangular solid, and has a rectangular shape in a plan view. Specifically, the resonator device 1 is 1.2 mm×1.0 mm in size in the plan view, and is 0.2 mm in thickness.

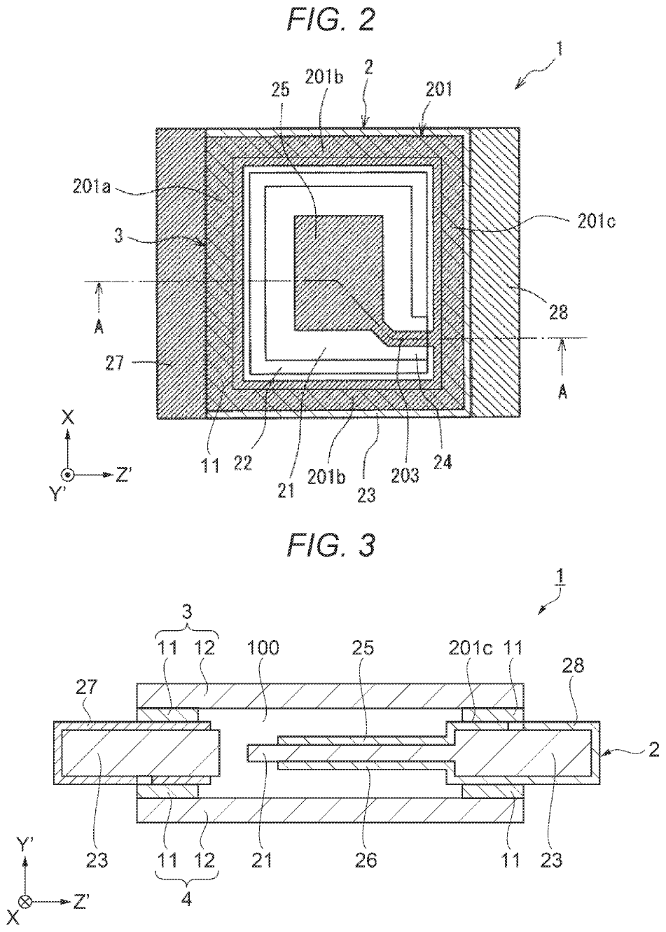

The quartz crystal vibrating plate 2 is an AT-cut quartz crystal plate obtained by processing a quartz crystal plate having a rectangular shape rotated 35° 15′ around an X axis as the crystal axis of quartz crystal, and the both of obverse and reverse principal surfaces thereof are each an X—Z′ plane. In the present embodiment, as shown in FIG. 2 and FIG. 4, a Z′ axis is set in a long-side direction of the quartz crystal vibrating plate 2 having the rectangular shape, and the Z axis is set in a short-side direction thereof.

The quartz crystal vibrating plate 2 is provided with a vibrating part 21 having a rectangular planar shape, a frame part 23 sandwiching the vibrating part 21 across a penetrating part 22, and a coupling part 24 for coupling the vibrating part 21 and the frame part 23 to each other. The frame part 23 is formed thicker than the vibrating part 21 and the coupling part 24. The first sealing member 3 and the second sealing member 4 are bonded to the frame part 23 via a bonding layer 11.

Further, the quartz crystal vibrating plate 2 has the vibrating part 21 having the rectangular planar shape coupled to the frame part 23 at a single place with the coupling part 24 provided to one of the corners of the vibrating part 21, and is therefore capable of reducing a stress acting on the vibrating part 21 compared to a configuration of coupling the vibrating part 21 at two or more places.

The coupling part 24 protrudes from one side along the X-axis direction out of an inner circumference of the frame part 23, and is formed along the Z′-axis direction. At both end portions in the Z′-axis direction of the quartz crystal vibrating plate 2, there are formed a first mounting terminal 27 and a second mounting terminal 28, respectively.

The first mounting terminal 27 and the second mounting terminal 28 are directly coupled to a circuit board or the like with soldering or the like. Therefore, it is conceivable that an oscillation frequency of the resonator device 1 becomes apt to vary by a contraction stress acting in the long-side direction (the Z′-axis direction) of the resonator device 1, and the stress propagating to the vibrating part 21. However, in the present embodiment, since the coupling part 24 is formed in a direction along the contraction stress, it is possible to prevent the contraction stress from propagating to the vibrating part 21. Thus, it is possible to suppress a variation in oscillation frequency when mounting the resonator device 1 on the circuit board.

On one surface of the vibrating part 21, there is formed a first excitation electrode 25 (see FIG. 2). On the other surface of the vibrating part 21, there is formed a second excitation electrode 26 (see FIG. 4). In the frame part 23 of one side part in the long-side direction (the Z′-axis direction) of the quartz crystal vibrating plate 2 having the rectangular planar shape, there is formed the first mounting terminal 27 electrically coupled to the first excitation electrode 25 along the short-side direction (the X-axis direction) of the quartz crystal vibrating plate 2. In contrast, in the frame part 23 of the other side part, there is similarly formed the second mounting terminal 28 electrically coupled to the second excitation electrode 26 along the short-side direction (the X-axis direction) of the quartz crystal vibrating plate 2. The first mounting terminal 27 and the second mounting terminal 28 are terminals for mounting the resonator device 1 to the circuit board or the like.

The first mounting terminal 27 is disposed continuously (see FIG. 2) to a first sealing pattern 201 having a rectangular annular shape. The second mounting terminal 28 is disposed continuously (see FIG. 4) to a second sealing pattern 202 having a rectangular annular shape. The first mounting terminal 27 and the second mounting terminal 28 are respectively formed in both end portions in the long-side direction (the Z′-axis direction) of the quartz crystal vibrating plate 2 across the vibrating part 21.

The first mounting terminal 27 and the second mounting terminal 28 are disposed on both principal surfaces of the quartz crystal vibrating plate 2, and the first mounting terminal 27 on one of the principal surfaces and the first mounting terminal 27 on the other of the principal surfaces are electrically coupled to each other via side-surface electrodes of the long sides opposed to each other of the quartz crystal vibrating plate 2 and an end-surface electrode of one of the short sides opposed to each other of the quartz crystal vibrating plate 2, and the second mounting terminal 28 on one of the principal surfaces and the second mounting terminal 28 on the other of the principal surfaces are electrically coupled to each other via side-surface electrodes of the long sides opposed to each other of the quartz crystal vibrating plate 2 and an end-surface electrode of the other of the short sides opposed to each other of the quartz crystal vibrating plate 2.

As shown in FIG. 2, on the obverse surface side of the quartz crystal vibrating plate 2, there is formed the first sealing pattern 201 to which the first sealing member 3 is bonded so as to have a rectangular annular shape and surround the vibrating part 21 having a substantially rectangular shape. The first sealing pattern 201 is provided with a connecting part 201a arranged continuously to the first mounting terminal 27, first extending parts 201b extending respectively from both end portions of the connecting part 201a along the long-side direction of the quartz crystal vibrating plate 2, and a second extending part 201c which extends along the short-side direction of the quartz crystal vibrating plate 2, and couples extension ends of the first extending parts 201b to each other.

The second extending part 201c is coupled to a first extraction electrode 203 which is extracted from the first excitation electrode 25. The first mounting terminal 27 is electrically coupled to the first excitation electrode 25 via the first extraction electrode 203 and the first sealing pattern 201.

Between the second extending part 201c extending along the short-side direction of the quartz crystal vibrating plate 2 and the second mounting terminal 28, there is disposed a non-electrode area where no electrode is formed, and thus, insulation between the first sealing pattern 201 and the second mounting terminal 28 is achieved.

As shown in FIG. 4, on the reverse surface side of the quartz crystal vibrating plate 2, there is formed the second sealing pattern 202 to which the second sealing member 4 is bonded so as to have a rectangular annular shape and surround the vibrating part 21 having the substantially rectangular shape. The second sealing pattern 202 is provided with a connecting part 202a arranged continuously to the second mounting terminal 28, first extending parts 202b extending respectively from both end portions of the connecting part 202a along the long-side direction of the quartz crystal vibrating plate 2, and a second extending part 202c which extends along the short-side direction of the quartz crystal vibrating plate 2, and couples extension ends of the first extending parts 202b to each other.

The second extending part 202c is coupled to a second extraction electrode 204 extracted from the second excitation electrode 26 via the connecting part 202a and the first extending parts 202b. The second mounting terminal 28 is electrically coupled to the second excitation electrode 26 via the second extraction electrode 204 and the second sealing pattern 202. Between the second extending part 202c extending along the short-side direction of the quartz crystal vibrating plate 2 and the first mounting terminal 27, there is disposed a non-electrode area where no electrode is formed, and thus, insulation between the second sealing pattern 202 and the first mounting terminal 27 is achieved.

As shown in FIG. 2, the width of each of the first extending parts 201b extending along the long-side direction of the quartz crystal vibrating plate 2 of the first sealing pattern 201 is narrower than the width of the frame part 23 extending along the long-side direction, and at both sides in the width direction (a vertical direction in FIG. 2) of each of the first extending parts 201b, there are disposed non-electrode areas where no electrode is formed.

Out of the non-electrode areas at both sides of each of the first extending parts 201b, the non-electrode area at an outer side extends up to the first mounting terminal 27, and is at the same time connected to the non-electrode area located between the second mounting terminal 28 and the second extending part 201c. Thus, an outer circumference of the connecting part 201a, the first extending parts 201b, and the second extending part 201c of the first sealing pattern 201 is surrounded by the non-electrode area which has an inverted C shape, and is substantially equal in width in the plan view.

At an inner side in the width direction of the connecting part 201a of the first sealing pattern 201, there is formed a non-electrode area. This non-electrode area is connected to the non-electrode area at the inner side of each of the first extending parts 201b. At an inner side in the width direction of the second extending part 201c, there is formed a non-electrode area except the first extraction electrode 203 in the coupling part 24. This non-electrode area is also connected to the non-electrode area at the inner side of each of the first extending parts 201b. Thus, an inner circumference in the width direction of the connecting part 201a, the first extending parts 201b, and the second extending part 201c of the first sealing pattern 201 is surrounded by the non-electrode area which has a rectangular annular shape, and is substantially equal in width in the plan view except the first extraction electrode 203 in the coupling part 24.

As shown in FIG. 4, the width of each of the first extending parts 202b extending along the long-side direction of the quartz crystal vibrating plate 2 of the second sealing pattern 202 is narrower than the width of the frame part 23 extending along the long-side direction, and at both sides in the width direction (a vertical direction in FIG. 4) of each of the first extending parts 202b, there are disposed non-electrode areas where no electrode is formed.

Out of the non-electrode areas at both sides of each of the first extending parts 202b, the non-electrode area at an outer side extends up to the second mounting terminal 28, and is at the same time connected to the non-electrode area located between the first mounting terminal 27 and the second extending part 202c. Thus, an outer circumference of the connecting part 202a, the first extending parts 202b, and the second extending part 202c of the second sealing pattern 202 is surrounded by the non-electrode area which has a C shape, and is substantially equal in width in the plan view.

At an inner side in the width direction of the connecting part 202a of the second sealing pattern 202, there is formed a non-electrode area except the second extraction electrode 204 in the coupling part 24. This non-electrode area is connected to the non-electrode area at the inner side of each of the first extending parts 202b. Further, at an inner side in the width direction of the second extending part 202c, there is formed a non-electrode area. This non-electrode area is also connected to the non-electrode area at the inner side of each of the first extending parts 202b. Thus, an inner circumference in the width direction of the connecting part 202a, the first extending parts 202b, and the second extending part 202c of the second sealing pattern 202 is surrounded by the non-electrode area which has a rectangular annular shape, and is substantially equal in width in the plan view except the second extraction electrode 204 in the coupling part 24.

As described above, the first extending parts 201b of the first sealing pattern 201 are made narrower in width than the frame part 23, and the non-electrode areas are disposed at both sides in the width direction of each of the first extending parts 201b. Further, at the inner side in the width direction of the connecting part 201a and the second extending part 201c, there are disposed the non-electrode areas.

Meanwhile, the first extending parts 202b of the second sealing pattern 202 are made narrower in width than the frame part 23, and the non-electrode areas are disposed at both sides in the width direction of each of the first extending parts 202b. Further, at the inner side in the width direction of the connecting part 202a and the second extending part 202c, there are disposed the non-electrode areas.

The non-electrode areas are formed by patterning the first sealing pattern 201 and the second sealing pattern 202 laid around to side surfaces of the frame part 23 when performing a sputtering process using a photolithographic technology, and then removing this using a metal etching process. Thus, it is possible to prevent short circuit caused by the first sealing pattern 201 and the second sealing pattern 202 laid around to the side surfaces of the frame part 23.

The first sealing member 3 and the second sealing member 4 which are bonded respectively to the obverse and reverse surfaces of the quartz crystal vibrating plate 2 to seal the vibrating part 21 of the quartz crystal vibrating plate 2 are each a resin film having a rectangular shape. The first sealing member 3 and the second sealing member 4 each have a size sufficient to cover a rectangular area except the first mounting terminal 27 and the second mounting terminal 28 in the both end portions in a longitudinal direction of the quartz crystal vibrating plate 2, and are bonded to the rectangular area.

The first sealing member 3 and the second sealing member 4 are each a heat-resisting resin film, and are each, for example, a film made of polyimide resin. The resin film is hereinafter referred to as a film 12. This film 12 has a heat-resisting property of about 300° C. The first sealing member 3 and the second sealing member 4 are transparent, but may become nontransparent in some cases depending on a condition of thermocompression bonding described later. It should be noted that the first sealing member 3 and the second sealing member 4 can be transparent, nontransparent, or semi-transparent.

It should be noted that the first sealing member 3 and the second sealing member 4 are not limited to polyimide resin, and it is possible to use resin classified into super engineering plastic such as polyamide resin or polyether ether ketone resin.

As shown in FIG. 3, the first sealing member 3 and the second sealing member 4 are bonded to the frame part 23 via the bonding layer 11. Specifically, the bonding layer 11 is arranged only in a region overlapping the frame part 23 as shown in FIG. 2 and FIG. 4. In other words, in the plan view, the bonding layer 11 does not exist in an area overlapping the vibrating part 21 such as a central portion of the resonator device 1, and is arranged only in an area having contact with the frame part 23. In other words, both of the obverse and reverse principal surfaces of the bonding layer 11 each function as a bonding portion.

In the first sealing member 3 and the second sealing member 4, a circumferential end portion having a rectangular shape thereof is thermocompression-bonded to the frame part 23 via the bonding layer 11 using, for example, hot press so as to seal the vibrating part 21. The bonding layer 11 is made of, for example, thermoplastic resin.

The first sealing member 3 and the second sealing member 4 are the heat-resisting resin films, and can therefore bear the high temperature in the solder-reflow process when solder-mounting the resonator device 1 on the circuit board or the like, and there is no chance for the first sealing member 3 and the second sealing member 4 to be deformed.

In contrast, regarding the bonding layers 11, when using the solder-reflow process, the solvent and so on evaporate from the bonding layers 11 to cause outgassing, and there is a possibility of making a harmful influence on the frequency fluctuation and so on of the quartz crystal vibrating plate 2. However, according to the present embodiment, since the film 12 has an area where the bonding layer 11 does not exist on a surface at the vibrating part 21 side, it is possible to reduce an amount of the outgas generated compared to when the bonding layer 11 exists on the entire surface of the resin film. Thus, it is possible to suppress the harmful influence exerting on the frequency fluctuation of the vibrating part 21.

The first excitation electrode 25 and the second excitation electrode 26 of the quartz crystal vibrating plate 2 are each constituted by stacking Au on a foundation layer made of, for example, Ti or Cr, and further stacking Ti, Cr, or Ni thereon. It should be noted that also in the first mounting terminal 27 and the second mounting terminal 28, the first sealing pattern 201 and the second sealing pattern 202, and the first extraction electrode 203 and the second extraction electrode 204, for example, substantially the same configuration is adopted.

In the present embodiment, the foundation layer is made of Ti, and Au and Ti are stacked thereon. As described above, since the uppermost layer is made of Ti, it is possible to increase the bonding strength with the polyimide resin compared to when Au is used as the uppermost layer.

An upper layer of each of the first sealing pattern 201 and the second sealing pattern 202 having a rectangular annular shape to which the first sealing member 3 and the second sealing member 4 are bonded is formed of Ti, Cr, or Ni (or oxides thereof) as described above, it is possible to increase the bonding strength between the first sealing member 3 and the second sealing member 4 compared to Au or the like.

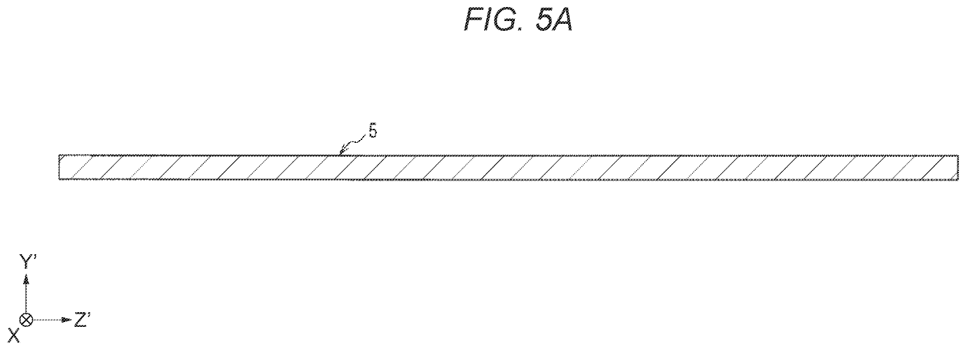

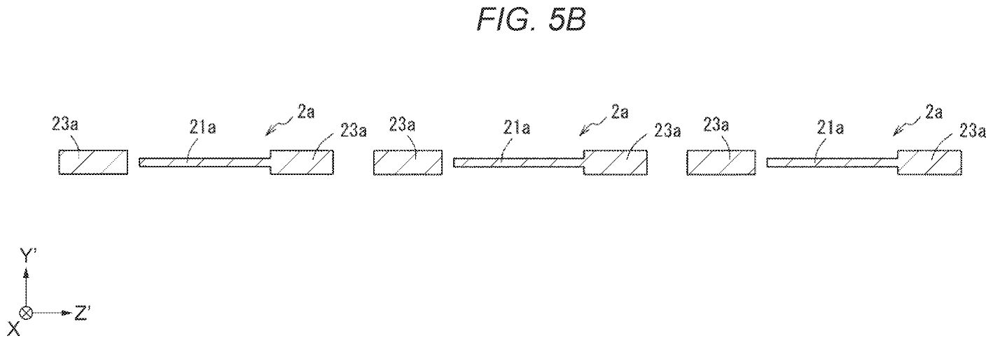

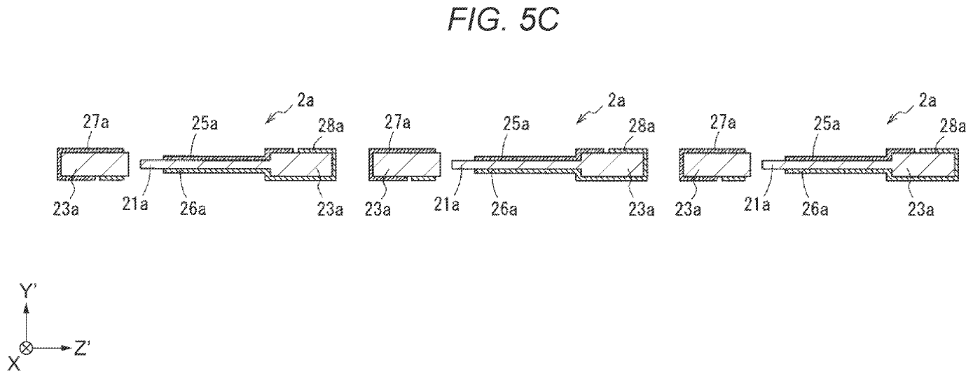

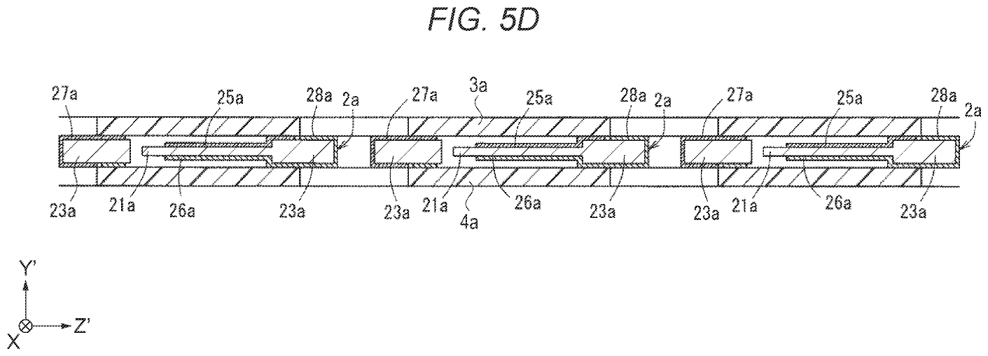

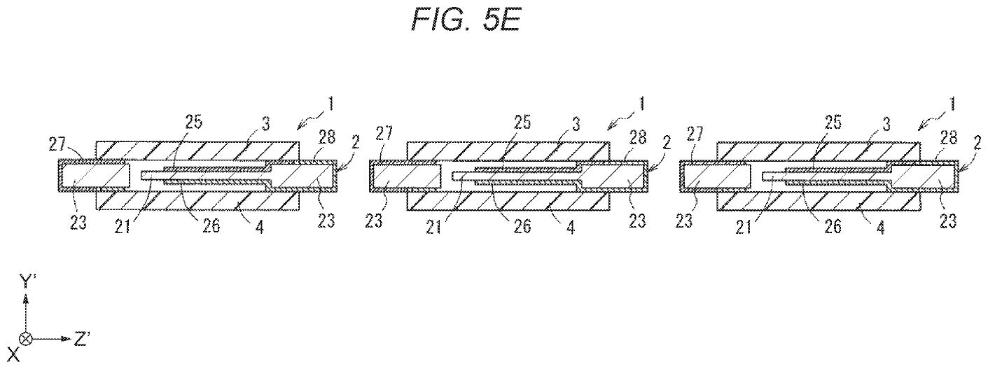

Then, a method of manufacturing the resonator device 1 will be described with reference to FIG. 5A through FIG. 5E.

First, in the step shown in FIG. 5A, a quartz crystal wafer (an AT-cut quartz crystal plate) 5 as an unprocessed wafer is prepared.

Then, in the step shown in FIG. 5B, for example, wet-etching is performed on the quartz crystal wafer 5 using the photolithographic technology and the etching technology to form an outer shape of each of the constituents such as a plurality of quartz crystal vibrating plates 2a and a frame part (not shown) for supporting these quartz crystal vibrating plates 2a, and further provide an outer shape of each of the constituents such as the frame part 23a and the vibrating part 21a thinner in wall than the frame part 23a to the quartz crystal vibrating plate 2a.

Then, in the step shown in FIG. 5C, the first excitation electrode 25a and the second excitation electrode 26a, the first mounting terminal 27a and the second mounting terminal 28a, and so on are formed at predetermined positions of the quartz crystal vibrating plate 2a using the sputtering technology or an evaporation technology, and the photolithographic technology.

Then, in the step shown in FIG. 5D, the first sealing member 3a and the second sealing member 4a are thermocompression-bonded so as to cover both of the obverse and reverse principal surfaces of the quartz crystal vibrating plate 2a with the first sealing member 3a and the second sealing member 4a, respectively, to seal the vibrating part 21a of each of the quartz crystal vibrating plates 2a. Sealing of the vibrating part 21a by the first sealing member 3a and the second sealing member 4a is performed in an inert gas atmosphere such as a nitrogen gas atmosphere.

Then, in the step shown in FIG. 5E, the first sealing member 3a and the second sealing member 4a are cut in accordance with each of the quartz crystal vibrating plate 2 so that the first mounting terminal 27 and the second mounting terminal 28 are partially exposed to remove unwanted portions, and then the quartz crystal vibrating plates 2 are separated into individual pieces. Thus, the plurality of resonator devices 1 shown in FIG. 1 can be obtained.

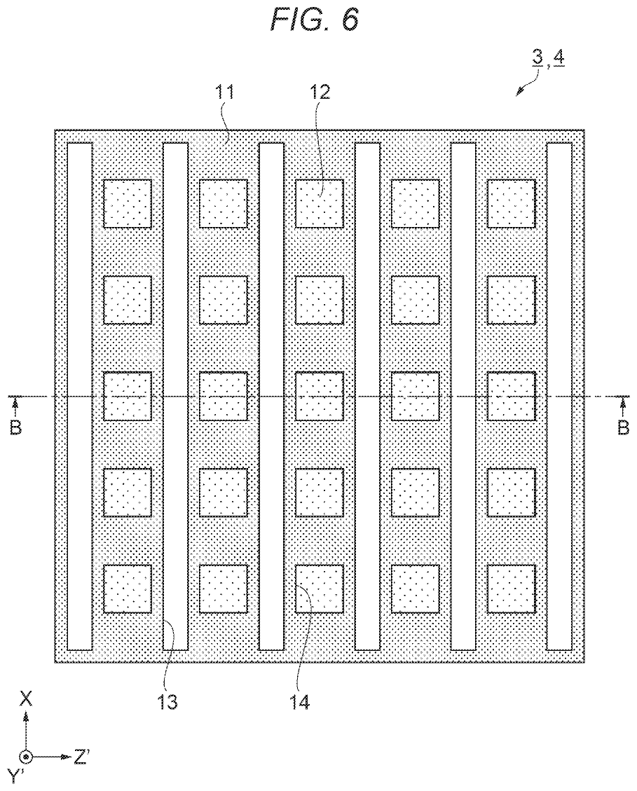

Then, a configuration of the first sealing member 3 and the second sealing member 4 will be described with reference to FIG. 6 and FIG. 7. Hereinafter, the description will be presented referring to the first sealing member 3 and the second sealing member 4 as sealing members 3, 4. Further, FIG. 6 and FIG. 7 show a state before the plurality of sealing members 3, 4 to be attached to the plurality of resonator devices 1 is separated into individual pieces.

As shown in FIG. 6 and FIG. 7, the sealing members 3, 4 have the film 12, the bonding layer 11 arranged on the film 12, and through holes 13 for separating the sealing members 3, 4 in the Z′-axis direction into individual pieces.

As described above, the sealing members 3, 4 have opening parts 14 as areas where the bonding layer 11 is absent in areas overlapping the vibrating parts 21 of the resonator device 1 in the plan view. By using such sealing members 3, 4, it is possible to form the plurality of resonator devices 1 at the same time.

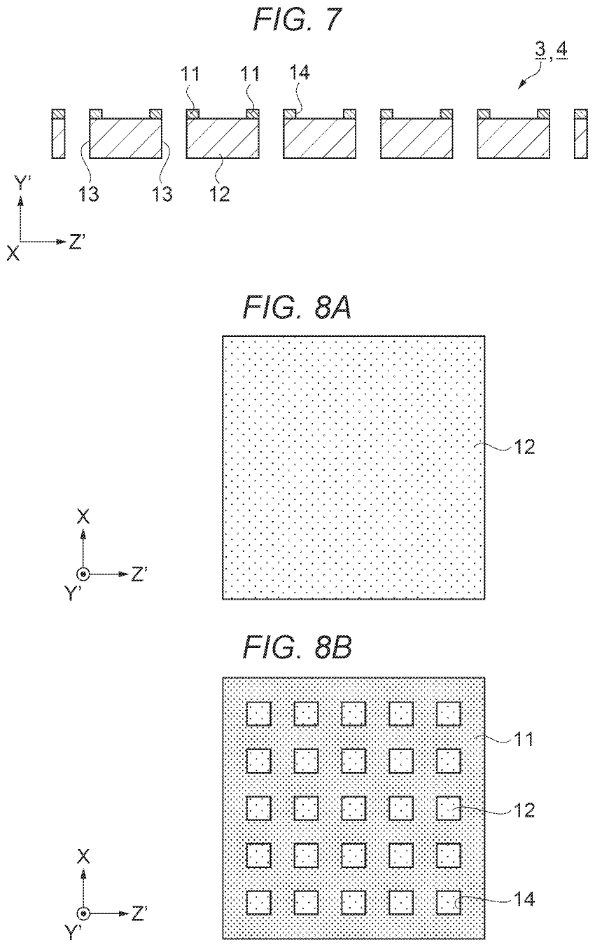

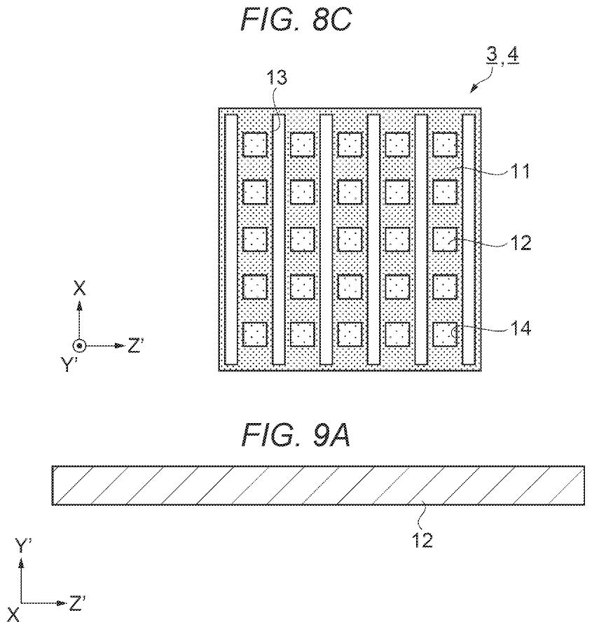

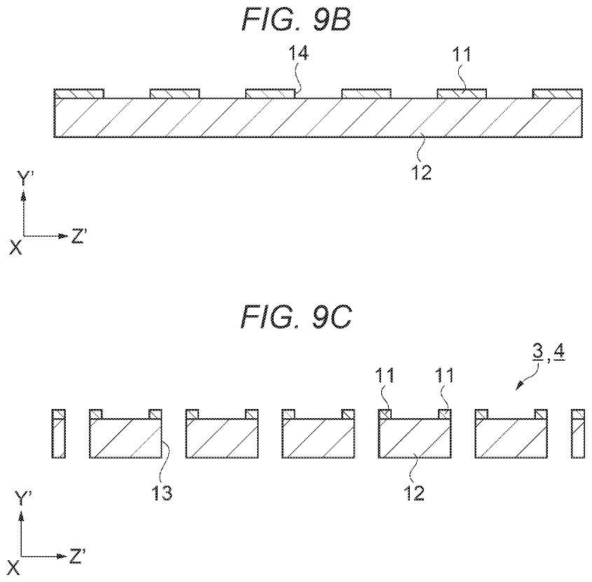

Then, a first formation method out of the methods of manufacturing the first sealing member 3 and the second sealing member 4 will be described with reference to FIG. 8A through FIG. 9C.

First, in the step shown in FIG. 8A and FIG. 9A, the film 12 is prepared.

Then, in the step shown in FIG. 8B and FIG. 9B, the film 12 and the bonding layer 11 are bonded to each other. It should be noted that in the bonding layer 11, the areas which overlap the vibrating parts 21 in the plan view, namely the opening parts 14, are removed in advance. Further, the bonding method described above is not a limitation, and it is possible to selectively deposit, apply, or print the bonding layer 11 only in an area where the bonding layer 11 is formed on the surface of the film 12.

Then, in the step shown in FIG. 8C and FIG. 9C, the through holes 13 are provided to the bonding layer 11 and the film 12. A method of forming the through holes 13 is not particularly limited, and it is possible to selectively cut the bonding layer 11 and the film 12 using a cutting method such as laser cut. Further, it is also possible to make the through holes 13 penetrate using an etching technology. Due to the above steps, the sealing members 3, 4 for forming the plurality of resonator devices 1 at the same time are completed.

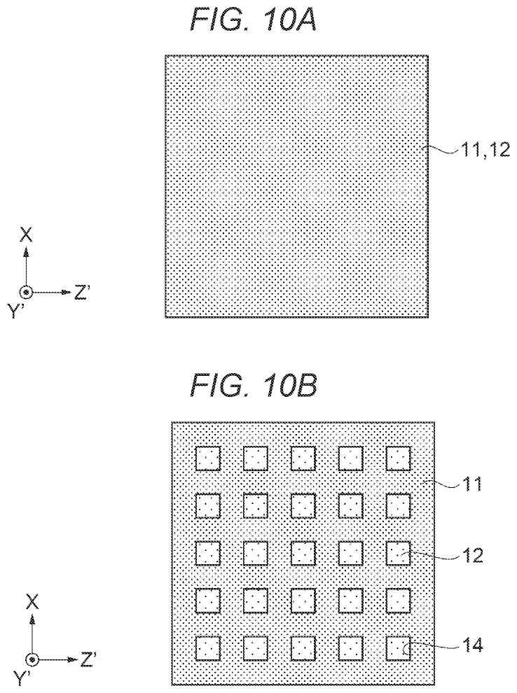

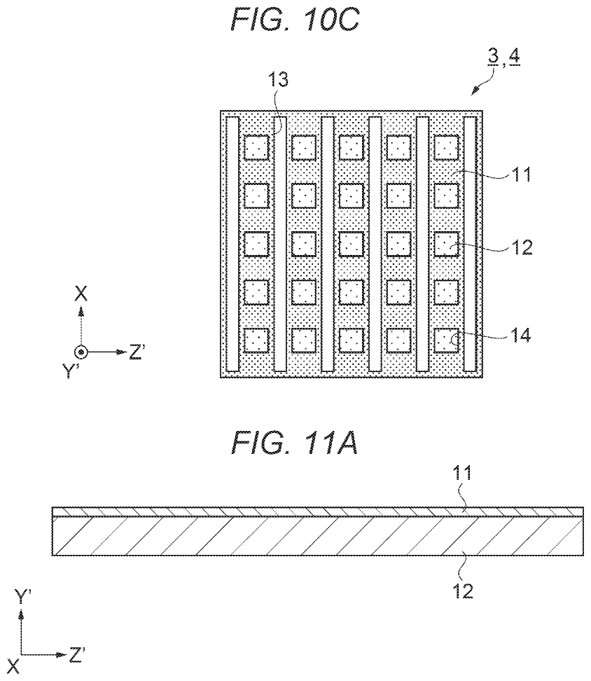

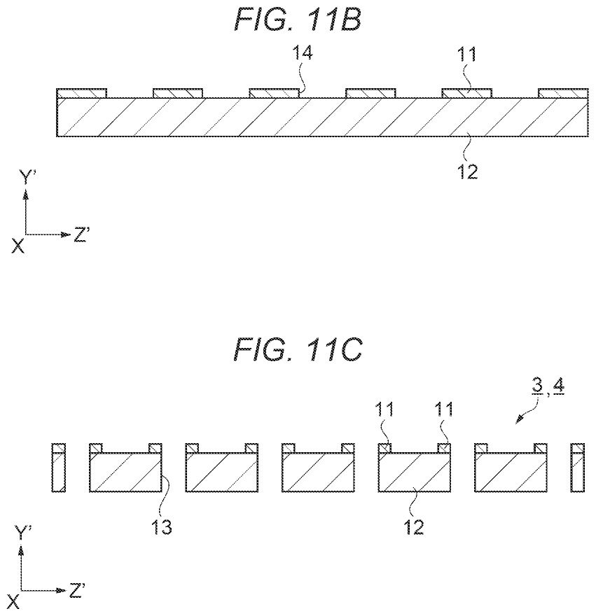

Then, a second formation method out of the methods of manufacturing the first sealing member 3 and the second sealing member 4 will be described with reference to FIG. 10A through FIG. 11C.

First, in the step shown in FIG. 10A and FIG. 11A, the film 12 attached with the bonding layer 11 is prepared. It should be noted that the bonding layer 11 is formed on the entire surface of the film 12 in advance.

Then, in the step shown in FIG. 10B and FIG. 11B, the bonding layer 11 in the areas corresponding to the opening parts 14 out of the bonding layer 11 deposited on the entire surface of the film 12 is removed. The method of forming the opening parts 14 is not particularly limited, and it is possible to, for example, perform patterning to remove only the areas of the opening parts 14.

Then, in the step shown in FIG. 10C and FIG. 11C, the through holes 13 are provided to the bonding layer 11 and the film 12. A method of forming the through holes 13 is not particularly limited, and it is possible to selectively cut the bonding layer 11 and the film 12 using, for example, such a cutting method as described above. Further, it is also possible to make the through holes 13 penetrate using an etching technology. Due to the above steps, the sealing members 3, 4 for forming the plurality of resonator devices 1 at the same time are completed.

As described hereinabove, the resonator device 1 according to the first embodiment is provided with the quartz crystal vibrating plate 2 having the vibrating part 21, and the frame part 23 surrounding the vibrating part 21 in the plan view, the first sealing member 3 bonded to one surface side of the quartz crystal vibrating plate 2, the second sealing member 4 bonded to the other surface side of the quartz crystal vibrating plate 2, and the bonding layer 11, wherein at least one of the first sealing member 3 and the second sealing member 4 is the film 12, the film 12 is bonded to the frame part 23 via the bonding layer 11, and has an area where the bonding layer 11 does not exist on the surface at the vibrating part 21 side.

According to this configuration, since the film 12 has the area where the bonding layer 11 does not exist, when the solvent evaporates from the bonding layers 11, it is possible to reduce an amount of the outgas generated compared to when the bonding layer 11 exists on the entire surface of the film 12. Thus, it is possible to suppress the harmful influence exerting on the frequency fluctuation of the quartz crystal vibrating plate 2. In addition, since the area of the bonding layer 11 is minimized, it is possible to suppress the cast for the bonding layer 11 to be used.

Further, in the resonator device 1 according to the first embodiment, it is preferable for the first sealing member 3 and the second sealing member 4 to be the film 12. According to this configuration, since both of them are the film 12, it is possible to suppress the cost therefor compared to when performing sealing with, for example, glass or a metal material.

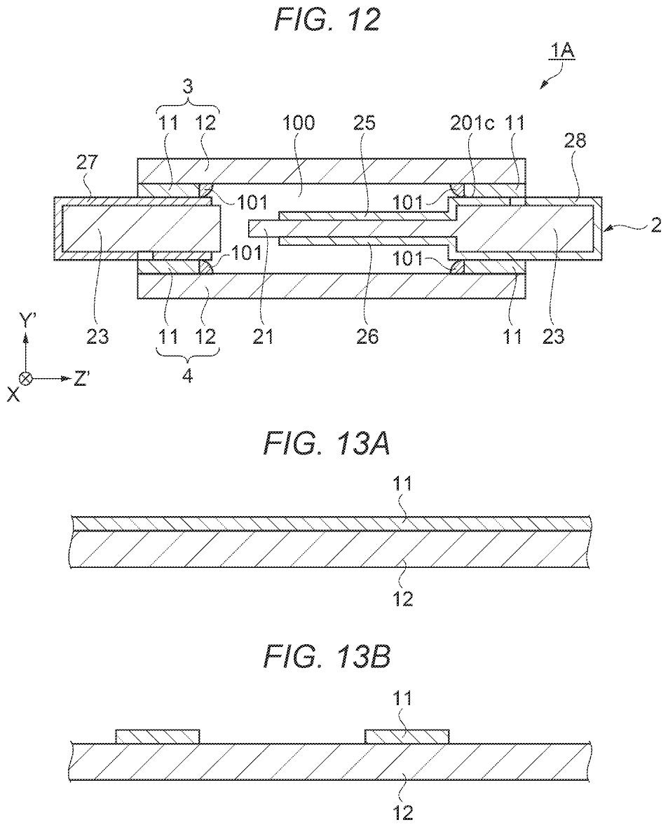

Then, a configuration of a resonator device 1A according to a second embodiment will be described with reference to FIG. 12.

As shown in FIG. 12, the resonator device 1A according to the second embodiment is different from the resonator device 1 according to the first embodiment in the part that the end surface at the vibrating part 21 side in the bonding layer 11 is covered with an inorganic film 101. The rest of the configuration is substantially the same. Therefore, in the second embodiment, the part in which the second embodiment is different from the first embodiment will be described in detail, and the description of other redundant parts will be appropriately omitted.

As shown in FIG. 12, in the resonator device 1A according to the second embodiment, the inorganic film 101 is arranged at the vibrating part 21 side in the bonding layer 11 of the first sealing member 3, namely a sealed space 100 side. Similarly, the inorganic film 101 is arranged at the vibrating part 21 side in the bonding layer 11 of the second sealing member 4, namely the sealed space 100 side.

The inorganic film 101 is preferably an outgas-proof dense film, and is made of, for example, silicon oxide (SiO₂) or titanium (Ti). In the case of titanium, it is possible to obtain both of, for example, an effect of reducing the generation of the outgas by covering the bonding layer 11, and an effect of adsorbing the outgas generated inside the space 100 as a cavity. The inorganic film 101 is formed using, for example, a CVD (Chemical Vapor Deposition) method.

As described above, since the end portion of the bonding layer 11 exposed at the space 100 side is covered with the inorganic film 101, it is possible to prevent the outgas generated from the bonding layers 11 from flowing toward the space 100.

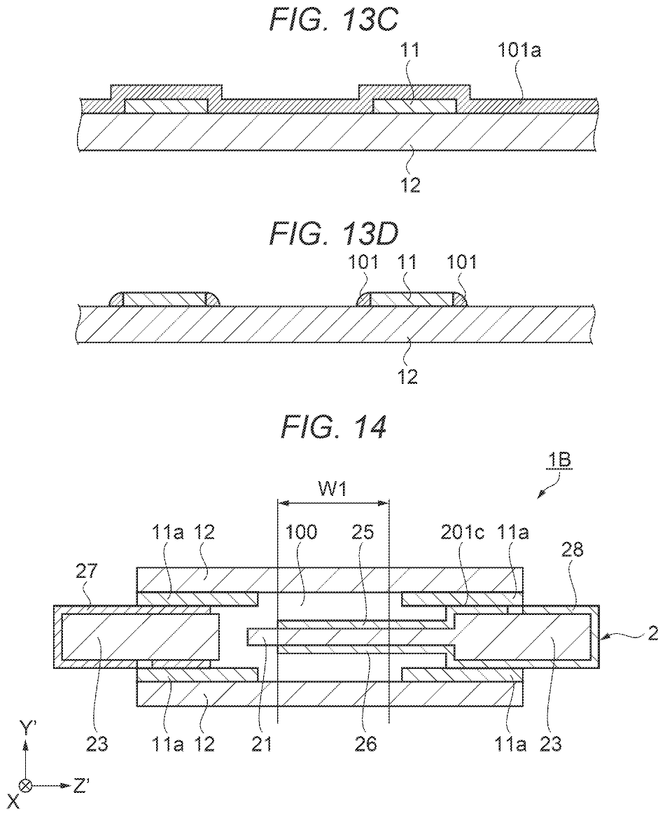

Then, a method of manufacturing the resonator device 1A according to the second embodiment will be described with reference to FIG. 13A through FIG. 13D. It should be noted that here, only a method of manufacturing the sealing members 3, 4 which is different from that of the resonator device 1 according to the first embodiment will be described.

First, in the step shown in FIG. 13A, there is prepared what is obtained by bonding the film 12 and the bonding layer 11 to each other. In the step shown in FIG. 13B, the bonding layer 11 is patterned. It should be noted that the steps up to the state shown in FIG. 13B are not particularly limited, and it is possible to use, for example, the method of manufacturing the sealing members 3, 4 in the first embodiment described above.

Then, in the step shown in FIG. 13C, the inorganic film 101a is deposited on the entire area of the film 12 including the bonding layer 11 thus patterned using, for example, the CVD method.

Then, in the step shown in FIG. 13D, for example, a dry etching process is performed on the film 12 to etch the inorganic film 101a in the vertical direction. Thus, it is possible to deposit the inorganic film 101 on the end surface of the bonding layer 11.

As described hereinabove, in the resonator device 1A according to the second embodiment, in the space 100 between the first sealing member 3 and the second sealing member 4, the end portion at the space 100 side in the bonding layer 11 is covered with the inorganic film 101. According to this configuration, since the end portion of the bonding layer 11 exposed at the space 100 side is covered with the inorganic film 101, it is possible to prevent the outgas generated from the bonding layers 11 from flowing toward the space 100.

Some modified examples of the embodiments described above will hereinafter be described.

As described above, the bonding layer 11 is not limited to be completely eliminated except the area having contact with the frame part 23, and can be arranged as shown in FIG. 14 through FIG. 17.

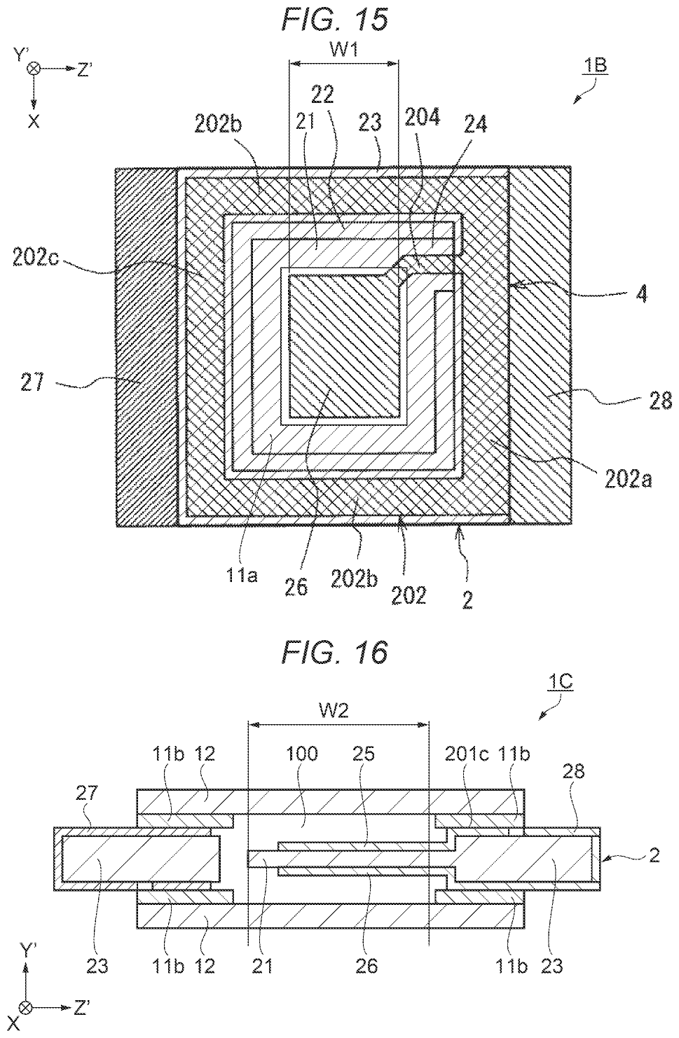

As shown in FIG. 14 and FIG. 15, in a resonator device 1B according to the modified example, bonding layers 11a in at least an area W1 overlapping the excitation electrodes 25, 26 are removed. According to this configuration, since the bonding layers 11a do not exist in the area W1 overlapping the excitation electrodes 25, 26, when the solvent evaporates from the bonding layers 11a, it is possible to suppress the influence of the outgas on the excitation electrodes 25, 26.

As described above, in the resonator device 1B according to the modified example, it is preferable to provide the vibrating part 21 with the excitation electrodes 25, 26, and it is preferable for the area where the bonding layers 11a do not exist to be the area overlapping at least the excitation electrodes 25, 26 in the plan view. According to this configuration, since the bonding layers 11a do not exist in the area overlapping the excitation electrodes 25, 26, when the solvent evaporates from the bonding layers 11a, it is possible to suppress the influence of the outgas on the excitation electrodes 25, 26.

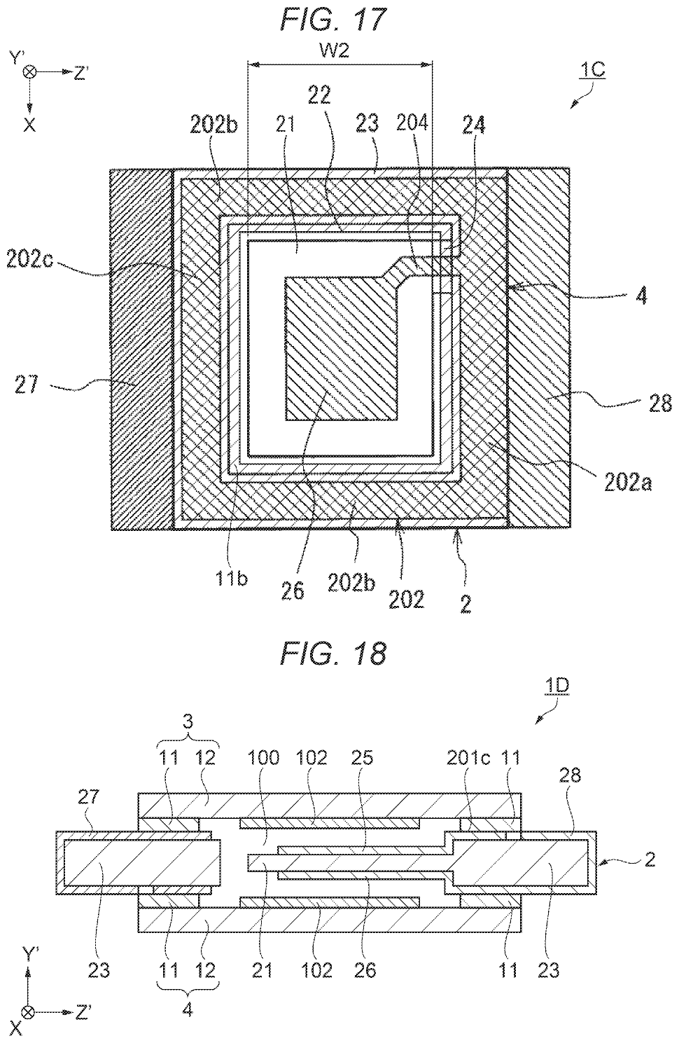

As shown in FIG. 16 and FIG. 17, in a resonator device 1C according to the modified example, bonding layers 11b in at least an area W2 overlapping the vibrating part 21 are removed. According to this configuration, since the bonding layers 11b do not exist in the area W2 overlapping the vibrating part 21, when the solvent evaporates from the bonding layers 11b, it is possible to suppress the influence of the outgas on the vibrating part 21.

As described above, in the resonator device 1C according to the modified example, it is preferable for the area where the bonding layers 11b do not exist to be the area overlapping at least the vibrating part 21 in the plan view. According to this configuration, since the bonding layers 11b do not exist in the area overlapping the vibrating part 21, when the solvent evaporates from the bonding layers 11b, it is possible to suppress the influence of the outgas on the vibrating part 21.

Further, as described above, the fact that nothing is disposed in the area where the bonding layers 11 are removed as described above is not a limitation, and it is possible to arrange adsorption layers 102 as shown in, for example, FIG. 18. Specifically, in a resonator device 1D according to the modified example, the adsorption layers 102 which adsorb the outgas are arranged in the areas where the bonding layers 11 do not exist, namely the areas overlapping the vibrating part 21, in the sealing members 3, 4.

As a constituent material of the adsorption layer 102, there can be cited, for example, activated charcoal, aluminum nitride (Al₂N₃), transition metal such as titanium (Ti), zirconium (Zr), niobium (Nb), tantalum (Ta), or vanadium (V), or alloys or compounds thereof such as Zr—V—Fe, Zr—V, or Zr—Al.

As described above, in the resonator device 1D according to the modified example, it is preferable to arrange the adsorption layers 102 in the areas where the bonding layers 11 do not exist. According to this configuration, since the adsorption layers 102 are arranged, when the outgas is generated, it becomes possible to adsorb the outgas, and thus, it is possible to suppress the influence of the outgas on the quartz crystal vibrating plate 2.

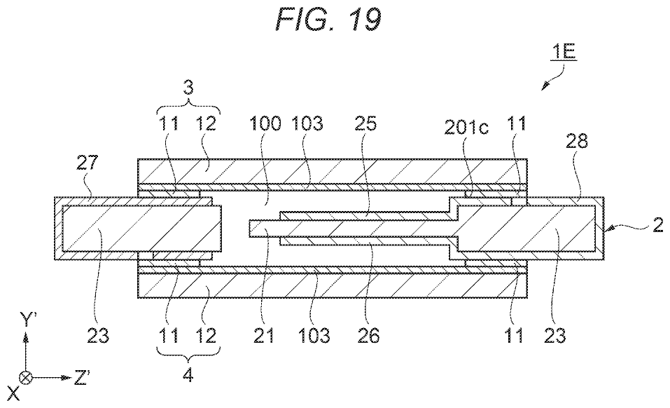

Further, as in a resonator device 1E according to the modified example shown in FIG. 19, it is possible to arrange an adsorption layer 103 in an area overlapping the bonding layer 11, namely on the entire surface at the vibrating part 21 side of the film 12. By adopting such a configuration, it is not necessary to pattern the adsorption layer 103, and therefore, it is possible to suppress the man-hour therefor. Further, since the adsorption layer 103 is arranged so as to overlap the bonding layer 11, it is possible to make it easier to adsorb the outgas.

As described above, in the resonator device 1E according to the modified example, it is preferable for the adsorption layer 103 to be arranged between the surface at the quartz crystal vibrating plate 2 side of the film 12 and the bonding layer 11. According to this configuration, since the adsorption layers 103 are arranged in the portions overlapping the bonding layers 11 in addition to the areas where the bonding layers 11 do not exist, when the outgas is generated, it becomes possible to adsorb the outgas, and thus, it is possible to further suppress the influence of the outgas on the quartz crystal vibrating plate 2. In addition, when arranging the adsorption layer 103 on the entire surface of the film 12, it is possible to easily form the adsorption layer 103 compared to when partially arranging the adsorption layer 103.

Further, as described above, the fact that both of the first sealing member 3 and the second sealing member 4 are the resin films is not a limitation, and it is possible to arrange that other materials such as a metal material or glass is applied to, for example, either one of the first sealing member 3 and the second sealing member 4.

What is claimed is:

1. A resonator device comprising:
a vibrating plate having a vibrating part and a frame part configured to surround the vibrating part in a plan view;
a first sealing member bonded to one surface side of the vibrating plate;
a second sealing member bonded to another surface side of the vibrating plate; and
a bonding layer, wherein
at least one of the first sealing member and the second sealing member is a resin film, and
the resin film is bonded to the frame part via the bonding layer, and has an area where the bonding layer does not exist on a surface at the vibrating part side.

2. The resonator device according to claim 1, wherein
the first sealing member and the second sealing member are each the resin film.

3. The resonator device according to claim 1, wherein
the vibrating part is provided with an excitation electrode, and
the area where the bonding layer does not exist is an area overlapping at least the excitation electrode in a plan view.

4. The resonator device according to claim 1, wherein
the area where the bonding layer does not exist is an area overlapping at least the vibrating part in a plan view.

5. The resonator device according to claim 1, wherein
an adsorption layer is arranged in the area where the bonding layer does not exist.

6. The resonator device according to claim 5, wherein
the adsorption layer is arranged between a surface at the vibrating plate side of the resin film and the bonding layer.

7. The resonator device according to claim 1, wherein
in a space between the first sealing member and the second sealing member, an end portion at the space side of the bonding layer is covered with an inorganic film.
